(19) United States
(12) Patent Application Publication
(10) Pub. No.: US 2026/0136452 A1
(43) Pub. Date: May 14, 2026

(54) Thermal Interface Under Component

(71) Applicant: ROCKWELL COLLINS, INC., Cedar Rapids, IA (US)

(72) Inventors: Andrew W. JENNINGS, Cedar Rapids, IA (US); Martin J. JENNINGS, Cedar Rapids, IA (US)

(73) Assignee: ROCKWELL COLLINS, INC., Cedar Rapids, IA (US)

(21) Appl. No.: 18/941,960

(22) Filed: Nov. 8, 2024

(51) Int. Cl. H05K 1/02; H05K 3/46

(52) U.S. Cl. CPC H05K 1/0206; H05K 1/0209; H05K 1/0269; H05K 3/4697; H05K 2201/066

(57) ABSTRACT

A thermal interface under component and method for making a thermal interface under component. The thermal interface under component includes a printed wiring board (PWB) and an electrical component. The electrical component is positioned adjacent to the PWB and is attached to the PWB by electrical connections which are positioned on a perimeter of the electrical component. Thermal interface material (TIM) is positioned between the PWB and the electrical component and within the perimeter formed by the electrical connections. The thermal interface material (TIM) is in conductive contact with both the PWB and the electrical component. The thermal interface material (TIM) may be injected via an injection hole in the PWB.

### FIELD OF THE INVENTION

The subject matter disclosed herein relates to improved under component heat sink structures for electrical components and, in particular, to thermal interface materials positioned between the underside of a component and the circuit board or circuit board precursor to which the component is mounted.

### BACKGROUND OF THE INVENTION

When trying to lower the temperature of a device that dissipates thermal energy, a common method is to simply relocate the energy. This is traditionally done with a heatsink (or “heat spreader”) positioned on the relevant component. A heatsink is a device which acts as a thermal conduit to transfer energy from one location to another location. The heatsink may be collocated with a high-power device so that heat transfer via conduction can help the energy move from the heat source to the heatsink.

Improved structures and method for transferring thermal energy away from heat generating components are desired. Especially desirable are thermal energy transfer methods which do not conflict with traditional circuit board architecture.

### SUMMARY OF THE INVENTION

The present disclosure is directed, in a first aspect, to a thermal interface under component including a printed wiring board (PWB), an electrical component, wherein said electrical component is positioned adjacent to the PWB and attached to the PWB by electrical connections, wherein the electrical connections are positioned on a perimeter of the electrical component, and a thermal interface material (TIM) positioned between the PWB and the electrical component and within the perimeter formed by the electrical connections, wherein the thermal interface material (TIM) is in conductive contact with both the PWB and the electrical component.

In another embodiment, the present disclosure is directed to a thermal interface under component where the PWB includes an injection hole positioned within the perimeter formed by the electrical connections.

In another embodiment, the injection hole is positioned in the center of the perimeter formed by the electrical connections. In another embodiment, the injection hole is filled with TIM.

In another embodiment, the PWB additionally comprises an observation hole wherein the observation hole is positioned within the perimeter formed by the electrical connections and traverses the PWB in a thickness direction.

In another embodiment, the PWB additionally comprises a first conductive surface layer comprised of a thermally conductive material positioned at a surface of the PWB which faces the electrical component and contacts the TIM. In another embodiment, the PWB additionally comprises thermal-vias wherein the thermal-vias are comprised of a thermally conductive material which traverses the PWB in a thickness direction and contacts the conductive surface layer. In another embodiment, the thermally conductive material is copper.

In another embodiment, the thermal interface under component further comprises a PWB-side heatsink positioned on the opposite side of the PWB as the electrical connections in a thickness direction.

In another embodiment, the PWB additionally includes a second conductive surface layer comprised of a thermally conductive material and positioned at a surface of the PWB which faces the PWB-side heatsink. The second conductive surface layer is in conductive contact with TIM positioned between the PWB and the PWB-side heatsink, and the TIM is in conductive contact with both the PWB and PWB-side heatsink.

In another embodiment, the thermal interface under component additionally comprises a component-side heat sink, wherein the component-side heat sink is positioned adjacent to the electrical component at a side of the electrical component which is opposite to the PWB. the component-side heat sink is in conductive contact with TIM positioned between the component-side heat sink and the electrical component, and the TIM is in conductive contact with both the component-side heat sink and the electrical component.

In another embodiment, a second aspect of the disclosure herein is directed to a method for producing a thermal interface under component includes injecting thermal interface material (TIM) into an injection hole provided in a printed wiring board (PWB). The injection hole provided in PWB is positioned within a perimeter formed by electrical connections which attach an electrical component to the PWB, and where the TIM fills the injection hole and a void area between the PWB and electrical component within the perimeter form by electrical connections.

In another embodiment, the PWB additionally comprises an observation hole wherein the observation hole is positioned within the perimeter formed by the electrical connections and traverses the PWB in a thickness direction.

In another embodiment, the method additionally includes stopping the injecting of the TIM upon observation through the observation hole that the TIM has filled the void area between the PWB and electrical component within the perimeter form by electrical connections.

In another embodiment of the method the PWB additionally comprises a first conductive surface layer comprised of a thermally conductive material positioned at a surface of the PWB which faces the electrical component and contacts the TIM.

In another embodiment of the method, the PWB additionally comprises thermal-vias wherein the thermal-vias are comprised of a thermally conductive material which traverse the PWB in a thickness direction and contact the conductive surface layer.

In another embodiment, the method additionally includes attaching a PWB-side heatsink to the PWB on a side of the PWB which is opposite to the electrical component by way of TIM which is provided between the PWB and the PWB-side heatsink, and the TIM is in conductive contact with both the PWB and the PWB-side heatsink.

In another embodiment, the method additionally includes attaching a component-side heat sink to the electrical component on a side of the electrical component which is opposite to the PWB by way of TIM which is provided between the electrical component and the component-side heat sink, and the TIM is in conductive contact with both the electrical component and the component-side heat sink.

In another embodiment, a third aspect of the disclosure herein is directed to a thermal interface under component including a printed wiring board (PWB), at least one electrical component, where the electrical component is positioned adjacent to the PWB and attached to the PWB by electrical connections, a shield which attaches to the PWB and encloses the at least one electrical component to define an enclosed area, and a thermal interface material (TIM) positioned within the between the enclosed area, wherein the TIM is in conductive contact with both the PWB and the electrical component.

In another embodiment, the PWB comprises an injection hole positioned within the enclosed area of the shield, and the enclosed area and the hole in the PWB are filled with TIM.

### BRIEF DESCRIPTION OF FIGURES

The features of the disclosure believed to be novel and the elements characteristic of the invention are set forth with particularity in the appended claims. The figures are for illustration purposes only and are not drawn to scale. The disclosure itself, however, both as to organization and method of operation, can best be understood by reference to the description of the preferred embodiment(s) which follows, taken in conjunction with the accompanying drawings in which:

FIG. 1 is a microscopic cross-sectional view of a heat source and heatsink interaction along a rough surface.

FIG. 2 is the same a microscopic cross-sectional view of the heat source and heatsink of FIG. 1 with a thermal interface material positioned at the interface of the heat source and heatsink.

FIG. 3 illustrates an exemplary embodiment with an imbedded a thermal conductor within a printed wiring board.

FIG. 4 illustrates three examples of electrical components suitable for thermal interface under component application.

FIG. 5 illustrates an exemplary embodiment of a thermal interface under component structure.

FIG. 6 illustrates another exemplary embodiment of a thermal interface under component structure.

FIG. 7. illustrates a top down view of an exemplary printed wiring board embodiment including a centrally placed injection hole.

FIG. 8 illustrates another top down view of an exemplary printed wiring board embodiment including a centrally placed injection hole and a conductive surface layer.

FIG. 9 illustrates an exemplary embodiment of a thermal interface under component structure in combination with a traditional component side heat sink.

FIG. 10 illustrates an exemplary embodiment of a thermal interface under component structure including a shielding component to provide thermal transfer from heat generating components.

### DETAILED DESCRIPTION OF THE INVENTION

The embodiments of the present disclosure can comprise, consist of, and consist essentially of the features and/or steps described herein, as well as any of the additional or optional ingredients, components, steps, or limitations described herein or would otherwise be appreciated by one of skill in the art.

As electronic components become smaller and component placement techniques become more precise, the industry is becoming capable of producing much smaller Circuit Card Assemblies (CCA). Some of these CCA's become so dense that they are produced and treated as their own stand-alone Commercial Off-The-Shelf (COTS) units which get built into larger systems. This is referred to as a System-On-Module (SOM). When the packaging density is further increased and the module is reduced to a machine-placeable component which resembles a microchip, this is called a System-In-Package (SIP).

This design and assembly approach allows for the creation of extremely space-conscious designs but also leads to a major technological issue, the thermal management and heat dissipation of the components within the SIP. What further complicates this challenge is that these SIPs include components on both sides of their internal substrate and typically the components on the bottom side of the card have a very restricted path of conduction cooling. Furthermore, the issue is present in other integrated components that have a high-power density.

There are inherent imperfections in the surfaces of the heat source and heatsink due to material types and manufacturing techniques which can lead to air pockets between the surfaces. Air pockets are detrimental to the thermal performance of the assembly because they act as thermal insulators which forces heat to travel through a convection mechanism which is much less efficient than a conduction mode.

To reduce this effect, Thermal Interface Materials (TIMs) may be used to function as a junction between a heat source and a heatsink. TIMs provide better thermal conductivity than air and fill the gaps which would otherwise have created air pockets between heat conducting materials, allowing for conduction cooling across the entire surface area. An improved method for applying a thermal interface material, between the underside of a component and the host-CCA to which it mounts is provided herein.

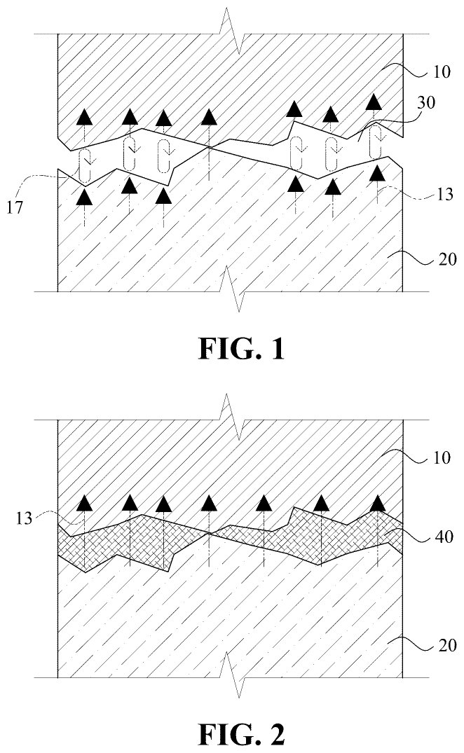

FIG. 1 illustrates a microscopic cross-sectional view of a heat source 20 and heatsink 10 interaction. The heat source 20 and heatsink 10 are positioned directly in contact with each other. However, due to surface roughness of each of the heat source 20 and heatsink 10 an air gap 30 is formed in spaces between the heat source 20 and heatsink 10 which fail to directly contact each other. The air gap 30 can form in multiple places along the interface of the heat source 20 and heatsink 10. In this air gap 30 only convection cooling 17 can occur.

The straight arrows 13 moving from the bottom of the figure to the top of the figure represent thermal transfer by conduction. The circular arrows 17 represent thermal transfer by convention.

FIG. 2 illustrates the same heat source 20 and heatsink 10 as in FIG. 1 but in FIG. 2, the air gap 30 has been replaced with Thermal Interface Materials (TIMs) 40. The TIMs 40 directly contact the surfaces of both the heat source 20 and heatsink 10 and enables conduction cooling 13 to occur across the entire surface area of the heat source 20 and heatsink 10 which the TIMs 40 contacts.

TIM's 40 discussed herein include thermally conductive materials which include, for example, thermal epoxy, thermal epoxy resin, thermally conductive paste, thermal grease, or other thermal management compound which is fluid or semifluid. Grease relies on external force to keep the heat source and heatsink in compression. Thermal pastes function to fill a gap between the heat source and heatsink and enable thermal conduction across the interface. The specific thermally conductive material selected for use as a TIM 40 in a particular embodiment should be suitable for being injected.

Typical TIMs 40 may be supplied in syringe-like containers with mixing nozzles which are used to apply the material at the thermal interface desired. This may be achieved through a manual pumping handle or a pneumatically driven applicator. The general method of applying TIMs 40 includes applying the TIMs 40 to a cavity in a heatsink 10 where the entire volume of the cavity or a partial volume of the cavity is filled prior to the Circuit Card Assembly (CCA), i.e., the heat source component 20, being mounted to the heatsink 10. This method results in material waste due to squeeze-out. This method of application of TIMs 40 also results in inconsistency in application caused by varying TIM 40 fill amounts. Additionally, application of TIMs can be challenging, restricted, or impossible if the area for application has been restricted, for example, during the assembly of other components.

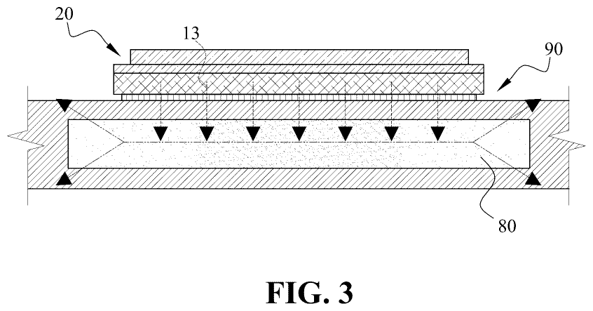

FIG. 3 illustrates another method of implementing conductive thermal migration by embedding a thermal conductor 80 depicted in FIG. 3 as, for example, a slug within a Printed Wiring Board (PWB) 90 or alternatively a printed circuit board (PCB). That is, the thermal conductor 80 is positioned inside the PWB 90 and facilitates thermal energy transfer through the PWB 90 via conduction 13. The thermal conductor 80 is made of a thermally conductive material, for example, copper. Examples of other conductive materials that may be used in the various conductive structures herein includes gold, nickel, silver, lead, and iron and various alloys including one or more of these materials. This embedding is implemented during the PWB 90 manufacturing process. In some embodiments, this is achieved by drilling a hole into the PWB 90 and placing a press-fit slug 80 into the drilled hole in the PWB 90 so that the slug 80 is completely exposed on top and bottom of the PWB 90.

In the embodiment shown in FIG. 3, this slug thermal conductor 80 is manufactured directly into the inner layers of the PWB 90 with additional circuit layers of the PWB 90 being added afterwards. This allows for signal routing to occur above and below the slug 80.

The present disclosure is directed to a Thermal Interface Under Component (TIUC) is a method that allows for the migration of thermal energy through the bottom of a component and through a PWB 90. It may be the case that the PWB 90 absorbs some thermal energy but the function of the PWB 90 is to transfer thermal energy though it, i.e., function as a heat spreader. The TIUC method can be implemented for electronic chips, or even for mechanical devices incorporating heatsinks.

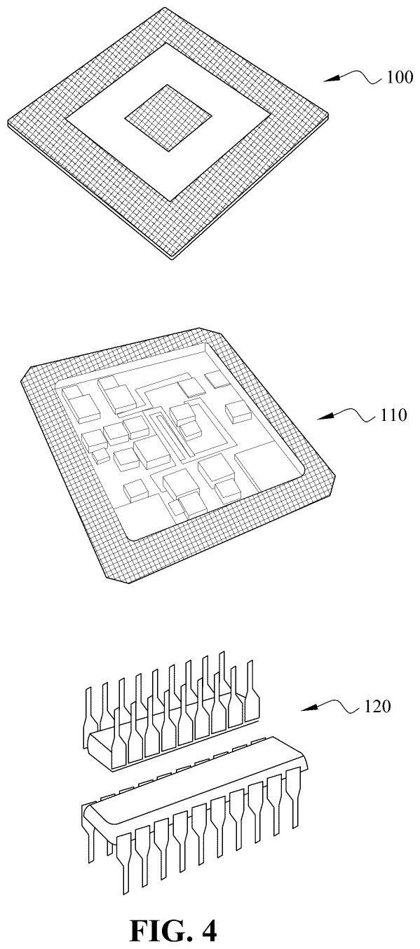

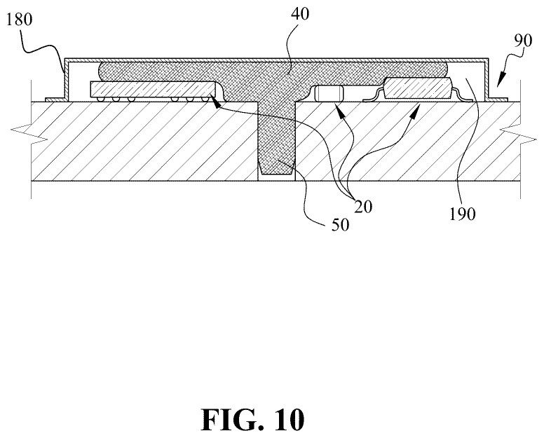

FIG. 4 illustrates examples of electrical components where the TIUC method may be employed. Such example components include, Ball Grid Arrays (BGA) 100, SIPs 110, and through-hole chips 120. Each of these components act as heat sources 20 in the TIUC. The TIUC structure and method may also be applied to other components that are not illustrated, for example, leaded integrated chips. The method may be applied to any component where there is a sufficient gap between the bottom of the component/heat source 20 and the PWB 90 for the TIM 40 to be added. Alternatively or additionally, the method may be applied to an application which employs a shield 180 structure which enclosures the electrical components 20 as depicted in FIG. 10 and discussed below.

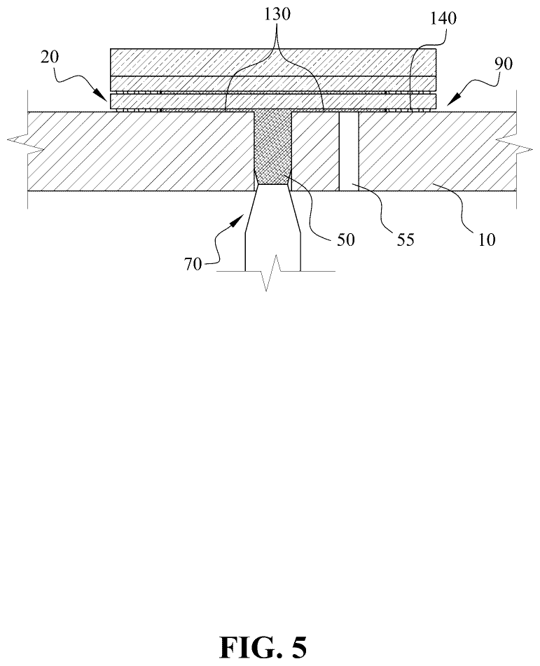

FIG. 5 illustrates a cross sectional view of an example embodiment of a TIUC structure. The TIUC structure depicted in FIG. 5 includes a component/heat source 20 attached to a PWB 90. Between the component/heat source 20 and PWB 90 is a layer of TIM 40. The TIM 40 fills an area 130 which is bounded by electrical connections 140 which attach the component/heat source 20 to the PWB 90. At least some amount of TIM 40 may also present in the injection hole 50 which is positioned in/through the PWB 90 and within the area 130. In some embodiments, the injection hole 50 is centrally located on the PWB 90 board with regard to the area 130 defined by the electrical connections (pins/pads) 140 which connect the component/heat source 20 and PWB 90.

The TIUC structure may also include an observation hole 55. The observation hole 55 traverses the PWB 90 in a thickness direction as shown in FIG. 5. The observation hole 55 is positioned within the area 130 defined by the electrical connections (pins/pads) 140 which connect the component/heat source 20 and PWB 90. The observation hole 55 functions to allow for inspection of the TIM 40 during injection to facilitate consistent fill amounts. Some amount of TIM 40 may also present in the observation hole 55. In addition, the observation hole 55 may function to allow for the release of displaced air inherent to the injection process of TIM 40.

The TIUC method is a method which can be used to create the TIUC structure. The method includes injecting thermal interface material (TIM) 40 into an injection hole 50 provided in a printed wiring board (PWB) 90 where the injection hole 50 provided in PWB 90 is positioned within an area 130 defined by a perimeter formed by electrical connections 140 which attached an electrical component 20 to the PWB 90. The TIM 40 fills the injection hole 50 and a void area 30 between the PWB 90 and electrical component 20 within the perimeter formed by electrical connections 140. In some embodiments an observation hole 55 is provided within the perimeter form by electrical connections 140 and an operator can use the observation hole 55 to inspect the filing process and know when to stop injecting the TIM 40, i.e., once the TIM 40 has filled the void area 30 between the PWB 90 and electrical component 20 within the perimeter form by electrical connections 140.

The TIUC method can be applied to any component where at least some area 130 exists between the bottom of the component/heat source 20 which is void of electrical connections (pins/pads) 140 so that the TIM 40 has an area 130 where it can be deployed. In other words, this method may not appropriate for component connections where the underside of the component is completely covered in, for example, solder ball connections and there is not a sufficient area 130 for TIM 40 to be placed in. Some examples of electrical devices where the TIUC method is acceptable are provided in FIG. 4 in the form of a BGA 110, SIP 110 and Through-Hole Chip 120.

As a part of implementing TIUC, a hole 50 may be drilled in the PWB 90 during a manufacturing step of making the PWB 90. The hole is positioned at a location suitable for having TIM 40, e.g., thermal paste, applied such that the TIM 40 may later be applied through the PWB 90 and into area 30. When implemented, thermal analysis simulations have shown improved thermal characteristics as compared to embodiments without TIM 40 in area 30 due to the increased thermal conductivity of the interface between the component/heat source 20 and the thermally conductive PWB 90. Thus, this structure is helpful for achieving a viable heat transfer approach in high-complexity designs where traditional cooling methods are insufficient. This arrangement is also suitable to function in conjunction with traditional cooling techniques. Either alone or combined with other cooling techniques, the TIUC improves the thermal management of a board-mounted device through the use of the board itself as a heat spreader.

The TIUC method includes the ability to be used as a retrofit or to be added after the card design is complete. The TIUC method may also be incorporated in, for example, a CCA design during the PWB 90 layout phase. The drilled injection hole 50 intended for thermal interface material 40 injection should be sized according to the anticipated TIM applicator nozzle 70 diameter. Additionally, the injection hole 50 may be placed at the approximate center of a component's 20 footprint to ensure consistent, radial expansion of the injected thermal interface material 40.

To assist in inspection of the TIM 40 application, a secondary inspection hole 55 may optionally also be placed at the edge of the intended TIM 40 injection volume so the injected material can be inspected by e.g., an operator, for consistent fill amounts. Alternatively, the amount of TIM 40 injected can be regulated based on the volume required to fill the area 130. For example, with equipment repeatedly used for the same task in a factory setting, specific volumes of material needed for a particular application can be determined and repeatedly applied without the need for the fill amount to be inspected with each TIM 40 application.

In most relevant implementations, resident air must also be considered. If a component is bonded to a PWB 90 with a process that seals air, for example, edge bond or underfill, the inspection hole 55 can double as a means to allow air to escape as paste fills the injection holes 50 and air gap 30. In the method, the injection holes 50 and air gap 30 are filled with TIM 40 e.g., thermal paste as designed and until visible at the inspection hole. However, paste is generally not to be allowed to enter or plug the inspection hole as this can create a sealed pocket of air and could create potential issues with thermal expansion/contraction of the trapped air.

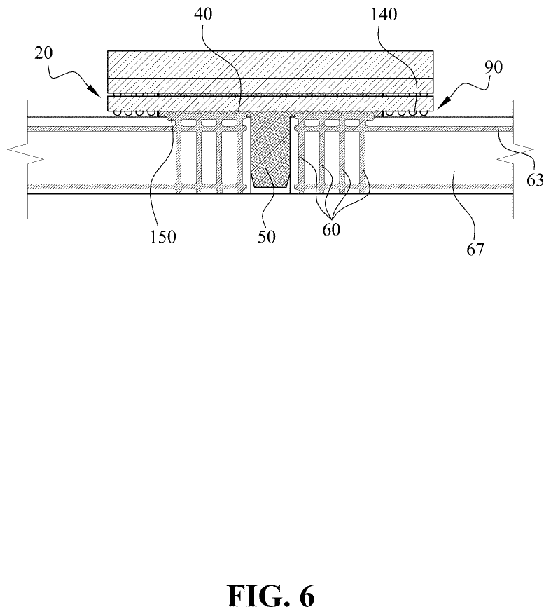

FIG. 6 illustrates a cross sectional view of another example embodiment of the TIUC method. To enhance heat transfer from the component and through the PWB 90, the PWB 90 may include a conductive surface layer 150, for example, an exposed copper layer positioned on the component 20 side of the PWB 90. In other embodiments, this exposed conductive surface layer 150 may be a portion of an embedded slug of conductive material 80. The PWB 90 also includes at least one thermal-via 60 which is a conductive pathway, for example, lines of copper, which traverse the PWB 90 and function to transfer electrical and/or thermal energy. In some embodiments, the PWB 90 is comprised of layers of copper 63 and fiberglass 67. The thermal-vias 60 traverse the fiberglass layers 67 and connect the copper layers 63 in the general direction which is perpendicular to the orientation of copper layers 63.

The exposed conductive surface layer 150 contacts the TIM 40 which contacts the component/heat source 20. These surface layers 150 can be well-bonded to internal copper layers 63 in PWB 90 to provide a thermally conductive heat transfer path for additional dissipation of thermal energy. The more thermally conductive the material used for the exposed surface layers 150 is, the more thermal energy is transferred and thus thermal transfer can be optimized within the PWB 90 as need. The TIM 40, exposed conductive surface layer 150, and thermal-vias 60 form a conductive chain from the component/heat source 20 through the PWB 90.

Examples of other conductive materials that may be used for thermal-vias 60 includes gold, nickel, silver, lead, and iron. In some embodiments, thermal-vias 60 structures may be in the form of hollow barrels of copper or other conductive material and/or filled with solder, e.g., tin, lead, silver.

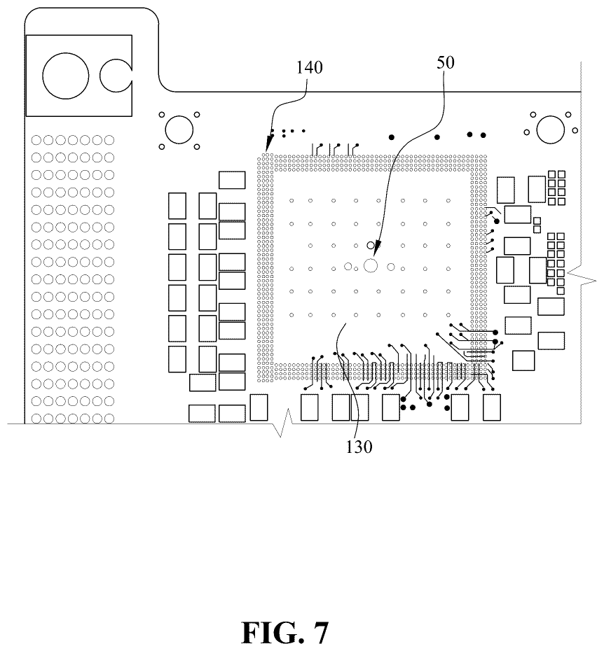

FIG. 7 illustrates a top down view of an exemplary PWB 90 including a centrally placed injection hole 50. The TIM 40 is be positioned throughout the injection hole 50 and in area 130 within the borders defined by electrical connections 140 where the component/heat source will be connected. The surrounding board illustrated in FIG. 7 is merely exemplary and not limiting to the scope of the TIUC structure or method as described herein.

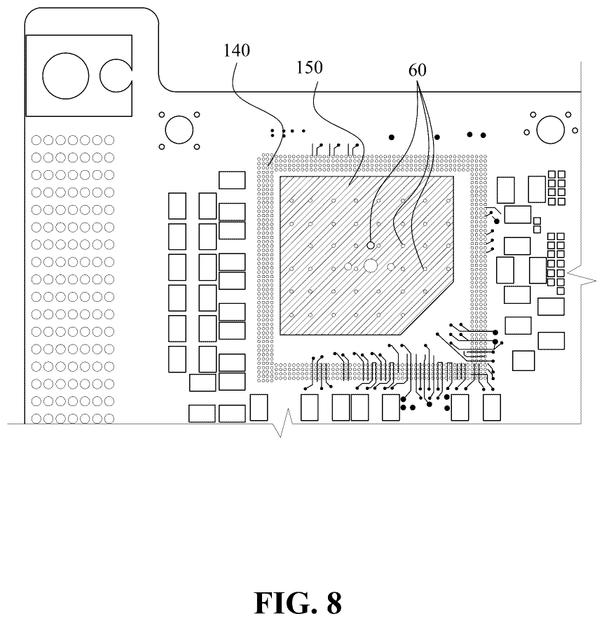

FIG. 8 illustrates a top down view of an exemplary PWB 90 including a centrally placed injection hole 50 and also having a conductive surface layer 150, for example, an exposed copper layer. In some embodiments, this exposed conductive surface layer 150 is a portion of an embedded slug. The PWB 90 also includes at least one thermal-via 60 which are conductive pathways, for example, lines of copper or other conductive material, which traverse the PWB 90 and function to transfer electrical and/or thermal energy through the board. In some embodiments, the PWB 90 is comprised of layers of copper and fiberglass. The thermal-vias 60 traverse the fiberglass layers and connect the copper layers in the direction perpendicular to the orientation of copper layers. The thermal-vias 60 may optionally also move in other directions through the PWB 90.

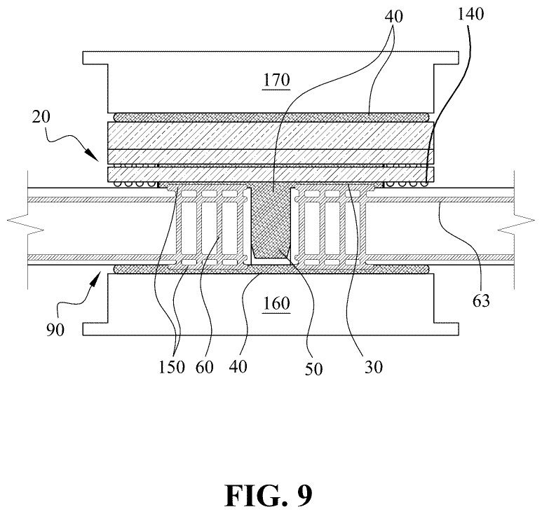

FIG. 9 illustrates an embodiment where the TIUC structure is combined with traditional heat sink structure. In the TUIC method, the step(s) of providing a TUIC structure is generally implemented before the PWB-side heatsink 160 is attached to the overall structure. The structure shown in FIG. 9, from top to bottom, includes a component-side heat sink 170 connected to the heat source/component 20 with TIM 40. The PWB 90 is positioned adjacent to the heat source/component 20 on the opposite side of the heat source/component 20 as the component-side heat sink 170 and connects to the heat source/component 20 through a second layer of TIM 40. The PWB 90 includes surface layers 150 which are bonded to internal copper layers 63 in the PWB 90 to provide a thermally conductive heat transfer path from the heat source/component 20 to the PWB-side heatsink 160 for additional dissipation of energy. This heat transfer path also includes a third layer of TIM 40 positioned between the PWB 90 and the PWB-side heatsink 160 to provide a conductive path from the PWB 90 to the PWB-side heatsink 160.

The combined TIUC method allows for efficient thermal transfer away from the component/heat source in two directions. The TIUC method specifically facilitates thermal energy transfer though the PWB 90 to the PWB-side heatsink 160 without interfering with the thermal transfer of thermal energy to the component-side heat sink 170 through traditional heat transfer methods.

The TIUC structure and method is advantageous and synergizes with traditional heat sinks because it maximizes the benefit of previously unusable space to provide improved thermal conduction in parallel with traditional PWB 90 features and increases the potential heat transfer pathways away from the heat source components 20. That is, it does not replace or impair either traditional heat sink methods and related structures, nor does it impair the function of the PWB 90. TIUC can thus be combined with other traditional thermal management methods, such as a traditionally applied heatsink 170 and thermal interface material 40 to the top of the component, to provide the most effective total cooling solution. This is particularly helpful when space constraints, high temperatures, or high heat loads necessitate additional cooling that traditional heat sink methods can not sufficiently provide.

The TIUC structure/method can also be used in combination with other thermal management features such as top mounted or PWB-side heat sinks or forced air cooling. Again, the TIUC method enables additional cooling performance without sacrificing any traditional cooling options. This is a synergistic improvement in performance.

Various TIUC implementations may be used to provide improved thermally coupling of the PWB 90 to the heat source/component 20. Additionally, in some TIUC implementations, thermal energy can be transferred into a component 20, for example, a temperature sensor to attain more accurate measurements. In some embodiments, the TIUC implementations can provide remote heating to a component in cold operating environments. That is, the TIUC implementations functions as an efficient thermal energy transfer path in a direction from high thermal energy to low thermal energy. In some implementations, that thermal energy transfer path will flow away from the component which is functioning as a heat source 20. In other implementations, that thermal energy transfer path will flow toward from the component which is functioning as a heat sink 10.

Regarding the order of installation of the components shown in FIG. 9, the heat source 20 is generally installed to the TIUC structure first. For example, to form a structure like that illustrated in FIG. 6. After the component/heat source 20 and TIUC structure are connected, assembly into the next-higher level mechanical installations with TIM 40 and heatsinks can be provided in a manner similar to installations using only the component/heat source 20. The resulting structure including that shown in FIG. 9

While the discussion herein focuses on under component thermal conductive cooling, the discussed TIUC method of through-card TIM 40 injection is also beneficial to other CCA design scenarios. For example, in a scenario where the next-higher assembly level process requires components to be hidden or made inaccessible by hardware such as solder-on electro-magnetic shielding cages, the TIUC method offers a means by which a TIM 40 can still be applied to enhance heat transfer out of a component or series of components. Such a structure is illustrated in FIG. 10.

FIG. 10 is a cross-sectional view of a TIUC embodiment structure including a shielding component to provide thermal transfer from heat generating components 20. In FIG. 10 a shield 180 is placed over the heat source/components 20. The shield 180 may be, for example, an electromagnetic interference shield. The shield 180 may be also be, for example, an inadvertent shielding structure formed by permanently placing heatsinking or other mechanical feature on the board. The shield 180 attaches to the PWB and encloses the electrical components 20 in an enclosed area 190. A hole 50 has been provided in the PWB 90 positioned within the enclosed area 190 of the shield 180 and TIM 40 has filled the drill hole 50 and the enclosed area 190 within the shield 180. As depicted in FIG. 10, the TIM 40 has only partially filed the area 190 within the shield 180. In some embodiments, the area 190 within the cover 180 is completely filed with TIM 40.

The TIUC method as applied to an embodiment illustrated in FIG. 10 injects the thermal interface material (TIM) 40 through an injection hole 50 provided in a printed wiring board (PWB) 90 where the injection hole 50 provided in PWB 90 is positioned within an enclosed area formed around the electrical connections 140 by the shield 180. The shield 180 is attached to the PWB 90 and encloses the electrical component 20 attached to the PWB 90. The TIM 40 fills some or all of the enclosed area 190 under the shield 180. The TIM 40 under the shield 180 is provided in a sufficient amount to form a thermally conductive interface with both the electrical component 20 and the PWB 90 and/or between the electrical component 20 and the shield 180 itself. In some embodiments an observation hole 55 is provided within the enclosed area 190 under the shield 180 and an operator can use the observation hole 55 to inspect the filling process and know when to stop injecting the TIM 40, i.e., once the TIM 40 has sufficiently filled the enclosed area 190.

Further to the advantages of the TIUC structure/method described above, the TIUC also enables new manufacturing process flows. For example, traditional process required that the board construction be completed prior to thermal management features being added. This is not a limitation using the TIUC method described herein. With the TIUC method, electrical components and mechanical components can be installed together first. This allows for, for example, soldered-on heat sinks 10, post-wave component installation, and complex next-level assembly instructions between multiple cards 90 which would have been precluded by a thermal interface material 40 being present. Then when complete, the TIM 40 can be injected as needed via hole 50 in the PWB 90. This is another surprising and unexpected benefit to the TIUC method beyond merely adding an additional means for transferring terminal energy to or from a component 20.

The TUIC structure can also function as a mitigation feature. In the cases where thermal simulations are immature and design cycle is short, the TUIC structure can help ensure sufficient thermal management can be achieved. Because there are no additional components or processes involved, the cost of implementation is minimal and yet it provides a valuable mitigation feature for future use. In this manner, the TUIC structure/method is a viable solution for situations where thermal management needs are uncertain.

The Thermal Interface Under Component (TIUC) creates a method to provide a conductive heat transfer path through the bottom of a component 20 and into a circuit card. The TIUC method can be implemented for electronic chips, or even to mechanical devices. At a minimum, the PWB 90 shall have a hole drilled in it during the manufacturing step so that the thermal interface material may later be applied through the PWB 90. A PWB 90 with an exposed conductive material 150 on the component side may have further improved heat conduction between the component 20 and the PWB 90. This may include a slug and/or many thermal-vias 60 to migrate thermal energy throughout the PWB 90. This low-cost method can assist in the thermal management of high-complexity or otherwise precluded designs and enable them to achieve a viable thermal solution for no additional recurring cost.

While the present disclosure has been particularly described, in conjunction with specific preferred embodiments, it is evident that many alternatives, modifications and variations will be apparent to those skilled in the art in light of the foregoing description. It is therefore contemplated that the appended claims will embrace any such alternatives, modifications and variations as falling within the true scope and spirit of the present disclosure.

What is claimed is:

1. A thermal interface under component comprising:
a printed wiring board (PWB),
an electrical component, wherein said electrical component is positioned adjacent to the PWB and attached to the PWB by electrical connections, wherein the electrical connections are positioned on a perimeter of the electrical component,
a thermal interface material (TIM) positioned between the PWB and the electrical component and within the perimeter formed by the electrical connections, wherein the thermal interface material (TIM) is in conductive contact with both the PWB and the electrical component.

2. The thermal interface under component of claim 1 wherein the PWB comprises an injection hole positioned within the perimeter formed by the electrical connections.

3. The thermal interface under component of claim 2 wherein the injection hole is positioned in the center of the perimeter formed by the electrical connections.

4. The thermal interface under component of claim 2 wherein the injection hole is filled with the TIM.

5. The thermal interface under component of claim 1 wherein the PWB additionally comprises an observation hole wherein the observation hole is positioned within the perimeter formed by the electrical connections and traverses the PWB in a thickness direction.

6. The thermal interface under component of claim 1 wherein the PWB additionally comprises a first conductive surface layer comprised of a thermally conductive material positioned at a surface of the PWB which faces the electrical component and contacts the TIM.

7. The thermal interface under component of claim 6 wherein the PWB additionally comprises of thermal-vias wherein the thermal-vias are comprised of a thermally conductive material which traverses the PWB in a thickness direction and contacts the conductive surface layer.

8. The thermal interface under component of claim 7 wherein the thermally conductive material is copper.

9. The thermal interface under component of claim 1 wherein the thermal interface under component further comprises a PWB-side heatsink positioned on the opposite side of the PWB as the electrical connections in a thickness direction.

10. The thermal interface under component of claim 9 wherein the PWB additionally comprises a second conductive surface layer comprised of a thermally conductive material and positioned at a surface of the PWB which faces the PWB-side heatsink,
wherein the second conductive surface layer is in conductive contact with TIM positioned between the PWB and the PWB-side heatsink, and
wherein the TIM is in conductive contact with both the PWB and PWB-side heatsink.

11. The thermal interface under component of claim 10 wherein the thermal interface under component additionally comprises a component-side heat sink, wherein the component-side heat sink is positioned adjacent to the electrical component at a side of the electrical component which is opposite to the PWB,
wherein the component-side heat sink is in conductive contact with TIM positioned between the component-side heat sink and the electrical component, and
wherein the TIM is in conductive contact with both the component-side heat sink and the electrical component.

12. A method for producing a thermal interface under component comprising:
injecting thermal interface material (TIM) into an injection hole provided in a printed wiring board (PWB),
wherein the injection hole provided in PWB is positioned within a perimeter formed by electrical connections which attach an electrical component to the PWB, and
wherein the TIM fills the injection hole and a void area between the PWB and electrical component within the perimeter form by electrical connections.

13. The method for producing a thermal interface under component of claim 12, wherein the PWB additionally comprises an observation hole wherein the observation hole is positioned within the perimeter formed by the electrical connections and traverses the PWB in a thickness direction.

14. The method for producing a thermal interface under component of claim 13, additionally comprising:
stopping the injecting of the TIM upon observation through the observation hole that the TIM has filled the void area between the PWB and electrical component within the perimeter form by electrical connections.

15. The method for producing a thermal interface under component of claim 12, wherein the PWB additionally comprises a first conductive surface layer comprised of a thermally conductive material positioned at a surface of the PWB which faces the electrical component and contacts the TIM.

16. The method for producing a thermal interface under component of claim 13, wherein the PWB additionally comprises thermal-vias wherein the thermal-vias are comprised of a thermally conductive material which traverse the PWB in a thickness direction and contact the conductive surface layer.

17. The method for producing a thermal interface under component of claim 12, additionally comprising:
attaching a PWB-side heatsink to the PWB on a side of the PWB which is opposite to the electrical component by way of TIM which is provided between the PWB and the PWB-side heatsink,
and wherein the TIM is in conductive contact with both the PWB and the PWB-side heatsink.

18. The method for producing a thermal interface under component of claim 12, additionally comprising:
attaching a component-side heat sink to the electrical component on a side of the electrical component which is opposite to the PWB by way of TIM which is provided between the electrical component and the component-side heat sink, and
wherein the TIM is in conductive contact with both the electrical component and the component-side heat sink.

19. A thermal interface under component comprising:
a printed wiring board (PWB),
at least one electrical component, wherein said electrical component is positioned adjacent to the PWB and attached to the PWB by electrical connections,
a shield which attaches to the PWB and encloses the at least one electrical component to define an enclosed area, and
a thermal interface material (TIM) positioned within the between the enclosed area, wherein the TIM is in conductive contact with both the PWB and the electrical component.

20. The thermal interface under component of claim 19 wherein the PWB comprises an injection hole positioned within the enclosed area of the shield, and
wherein the enclosed area and the hole in the PWB are filled with TIM.
